(19) United States
(12) Patent Application Publication
(10) Pub. No.: US 2012/0081194 A1
(43) Pub. Date: Apr. 5, 2012

(54) Vehicle-Mounted Noise Filter

(75) Inventors: Yasuhiko Nishioka, Tokyo (JP); Hidekazu Kobayashi, Tokyo (JP)

(73) Assignee: HARADA INDUSTRY CO., LTD, Tokyo (JP)

(21) Appl. No.: 13/322,901

(22) PCT Filed: May 18, 2010
(86) PCT No.: PCT/JP2010/058364

§ 371 Date: Nov. 28, 2011

(30) Foreign Application Priority Data
May 29, 2009 (JP) 2009-131374

(51) Int. Cl. H03H 7/01

(52) U.S. Cl. 333/185; 333/181

(57) ABSTRACT

Disclosed is a vehicle-mounted noise filter capable of suppressing electric field coupling between a pair of capacitors in the FM radio band, thereby allowing the intrinsic noise attenuation performance of a noise filter circuit to be exerted even in the FM radio band. The vehicle-mounted noise filter comprises a ground plate, a coil, a pair of capacitors, and a conductive shielding plate. The ground plate is grounded in a vehicle body. A lead wire is wound around the coil. The pair of capacitors are disposed such that the coil is interposed therebetween, and are electrically connected to the coil and the ground plate so as to form π-type filter circuit. The conductive shielding plate is grounded in the ground plate and is disposed between the pair of capacitors so as to shield the electric field coupling between the pair of capacitors.

### TECHNICAL FIELD

The present invention relates to a vehicle-mounted noise filter, and more particularly to a vehicle-mounted noise filter capable of improving noise attenuation performance even in FM radio band (very high frequency band).

### BACKGROUND ART

Various types of noise filters for removing noise of a vehicle-mounted electric component have been developed. For example, a defogger wire and a radio antenna are often provided together on the same rear window of a vehicle. In such a case, a noise filter is connected in series to a wiring for supplying power to the defogger wire so as to prevent, e.g., AM radio from being adversely affected by noise superimposed on the wiring.

In view of an installation space and influences on vehicle performance, a vehicle-mounted noise filter is required to be small in size and light in weight. For example, Patent Document 1 discloses a noise filter capable of achieving a reduction in size and heat radiation. In Patent Document 1, a noise filter constituted by a π-type low-pass filter is taken as an example. This noise filter has a filter circuit having a function of allowing a direct current to pass therethrough and achieves the maximum noise suppression amount (insertion loss) in AM radio band (medium- to short-wave band).

In recent years, control of vehicle-mounted electric components has become increasingly sophisticated and the number of systems to be controlled has become large. Under such circumstances, many Electric Control Units (ECUs) have come to be adopted. The operating speed of the ECU has become faster and, correspondingly, the noise occurrence frequency is increased and noise frequency becomes higher, resulting in adverse affect also on the FM radio.

A sufficient noise suppression amount can be obtained for the AM radio band by using a conventional noise filter, e.g., the noise filter disclosed in Patent Document 1, however, for the FM radio band, a sufficient noise suppression amount cannot often be obtained. This is because input-side noise does not pass through a filter circuit but directly leaks to the output side due to influence of the electric filed coupling between the input and output terminals of the noise filter, which prevents attainment of a sufficient noise attenuation amount.

To solve the above problem, the present inventor has disclosed in Japanese Patent Application No. 2008-138750 a vehicle-mounted noise filter capable of providing high noise attenuation performance even in FM radio band by using a shielding plate for shielding electric field coupling between input and output terminals.

Such a vehicle-mounted noise filter is of a π-type configuration wherein one coil is disposed between two capacitors (capacitor-coil-capacitor). The two capacitors are disposed opposite to each other because of the requirement of size reduction. Around the AM radio band, the filter circuit having such a configuration achieves a large attenuation amount by producing a series resonance between the capacitor body and a capacitor lead wire.

### CITATION LIST

### Patent Document

Patent Document 1: International Publication No. 2007/020902 Brochure

### DISCLOSURE OF THE INVENTION

### Problems to be Solved by the Invention

In designing a filter for the FM radio band by using the above-mentioned vehicle-mounted noise filter circuit configuration mainly supporting the AM radio band, the following behaviors of each element need to be taken into consideration. That is, in a high-frequency band, a capacitor part functions as an equivalent series inductor. Further, the coil part exhibits a high inductance value in the AM radio band by using a magnetic core, however, in a high-frequency band, the inductance gets lower due to influence of a reduction in the magnetic permeability, and coupling capacitance between the coils appears, with the result that the coil part becomes equivalent to a parallel circuit of a coil and coupling capacitance. Therefore, in a high-frequency band such as the FM radio band, the noise filter does not assume a π-type configuration wherein one coil is disposed between two capacitors (capacitor-coil-capacitor) but assumes a configuration of an equivalent series inductor of capacitor part—an equivalent parallel circuit of coil part inductor and coupling capacitance—an equivalent series inductor of capacitor part.

However, a pair of input-side and output-side capacitors of the noise filter are disposed opposite to each other in the actual mounting conditions for size reduction of the entire noise filter and, eventually, the capacitors behave as a coupled line shorting terminations with each other. Thus, attenuation design using only the equivalent series inductor was insufficient.

In view of the above situation, the present invention has been made and an object thereof is to provide a vehicle-mounted noise filter capable of suppressing electric field coupling between a pair of capacitors in the FM radio band and allowing a noise filter circuit to provide its original noise attenuation performance even in the FM radio band.

### Means for Solving the Problems

According to one aspect of the invention, there is provided a vehicle-mounted noise filter comprising: a ground plate for grounding to a vehicle body; a coil around which a conducting wire is wound; a pair of capacitors disposed so as to sandwich the coil and electrically connected to the coil and the ground plate so as to provide a π-type filter circuit; and a conductive shielding plate disposed between the pair of capacitors so as to shield electric field coupling between the pair of capacitors and grounded to the ground plate.

The conductive shielding plate may be disposed between one coil and each of the pair of capacitors.

The conducting wire of the coil may be wound in such a direction so as to generate a leakage electric field in the direction canceling the electric field of the electric field coupling, generated between the pair of capacitors.

When the capacitor connected to an input terminal side is disposed on the axially right side of the coil as viewed from the input terminal of the vehicle-mounted noise filter, the coil may be wound right-handed, while when the capacitor connected to the input terminal side is disposed on the axially left side of the coil, the coil may be wound left-handed.

The pair of capacitors may be disposed such that surfaces thereof smaller in area are opposed to each other so as to reduce the opposing area.

At this time, the pair of capacitors may be disposed opposite to each other so as to sandwich the coil from both side parallel to the direction perpendicular to the axis of the coil.

The ground plate may have a flared portion for fixing to the vehicle body, and at least part of the flared portion may be disposed between the opposing pair of capacitors.

The flared portion may be formed so as to make equal the distances therefrom to connection points at which the pair of capacitors are connected respectively to the ground plate.

The conducting wire may be wound around the coil such that the end portions of the conducting wire at both ends of the coil extend in the same direction and are at the same height position.

The flared portion may have a temporary latching claw to be latched in a temporary latching hole formed in the vehicle body.

### Advantages of the Invention

The vehicle-mounted noise filter according to the present invention suppresses electric field coupling between the pair of capacitors to thereby provide high noise attenuation performance even in FM radio band.

### BRIEF DESCRIPTION OF THE DRAWINGS

FIG. 1 is a schematic view for explaining an arrangement example of components of a vehicle-mounted noise filter according to a first embodiment of the present invention.

FIG. 2 is a schematic view for explaining an arrangement example of components of a vehicle-mounted noise filter according to a second embodiment of the present invention.

FIG. 3 is a graph of input/output characteristics with respect to the frequency of the vehicle-mounted noise filter of the present invention.

FIG. 4 is a schematic view for explaining an arrangement example of components of a vehicle-mounted noise filter according to a third embodiment of the present invention.

FIG. 5 is a top view for explaining the electric field direction in the vehicle-mounted noise filter according to the present invention.

FIG. 6 is a top view for explaining an example in which the coil winding direction and the arrangement position of the capacitors in the vehicle-mounted noise filter according to the present invention illustrated in FIG. 5 are reversed.

FIG. 7 is a graph of input/output characteristics with respect to the frequency of the vehicle-mounted noise filter for explaining influence on the input/output characteristics due to a difference in the coil winding direction.

FIG. 8 is a top view for explaining a state where a left-handed-wound coil and capacitors of the vehicle-mounted noise filter are arranged in the same manner as in FIG. 6.

FIG. 9 is a schematic view for explaining an arrangement example of components of a vehicle-mounted noise filter according to a fourth embodiment of the present invention.

FIG. 10 is a perspective view for explaining an example of the flared portion of the ground plate of the vehicle-mounted noise filter according to the present invention.

### PREFERRED EMBODIMENTS OF THE INVENTION

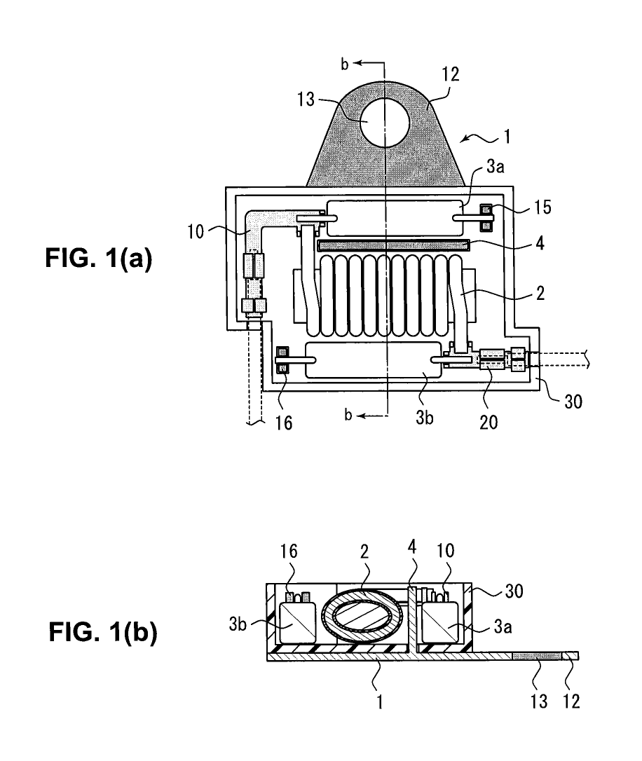

Preferred embodiments of the present invention will be described below with reference to the accompanying drawings. FIG. 1 is a schematic view for explaining an arrangement example of components of a vehicle-mounted noise filter according to a first embodiment of the present invention. FIG. 1 (a) is a top view, and FIG. 1 (b) is a cross-sectional view taken along the b-b line of FIG. 1 (a). As illustrated, a vehicle-mounted noise filter according to the first embodiment of the present invention mainly includes a ground plate 1, a coil 2, a pair of capacitors 3a and 3b, and a conductive shielding plate 4. These components are housed in a casing 30 made of an insulating material.

The ground plate 1 is provided for grounding of a vehicle body. When the noise filter is mounted, the ground plate 1 is fixed to the vehicle body (not illustrated) and is electrically connected to the noise filter. The ground plate 1 is disposed on the rear surface side of the casing 30 so as to cover substantially the entire rear surface of the casing 30. Ground terminals 15 and 16 are electrically connected to the ground plate 1. The ground terminals 15 and 16 each extend through a predetermined through-hole formed in the casing 30 so as to be disposed inside the casing 30. For example, the ground terminals 15 and 16 may be formed by bending at right angles a part of the sheet-like ground plate 1 to raise it upright or may be electrically connected to the ground plate 1 by soldering, etc. Further, the ground plate 1 has a flared portion 12 in which a connection hole 13 through which a screw (not illustrated) is screwed to the vehicle body. The vehicle-mounted noise filter is screwed to the vehicle body through the connection hole 13.

The coil 2 is obtained by winding a conductive wire. In this illustrative example, winding the conductive wire around a magnetic core increases the inductance of the coil 2. A first terminal of the coil 2 is connected to an input terminal 10 of the noise filter, and a second terminal thereof is connected to an output terminal 20 of the noise filter. A wiring for external connection is electrically connected to the input terminal 10 and the output terminal 20, respectively.

The pair of capacitors 3a and 3b constitute a π-type filter circuit together with the coil 2. The pair of capacitors 3a and 3b are disposed so as to sandwich the coil 2 therebetween. More specifically, in this illustrative example, the pair of capacitors 3a and 3b sandwich the coil 2 from both sides parallel to the axial direction of the coil 2. A first terminal of the capacitor 3a is connected to the input terminal 10, and a second terminal thereof is connected to a ground terminal 15. Meanwhile, a first terminal of the capacitor 3b is connected to a ground terminal 16, and a second terminal thereof is connected to the output terminal 20. That is, the first terminal of the capacitor 3a is electrically connected to the first terminal of the coil 2 through the input terminal 10, and the second terminal of the capacitor 3b is electrically connected to the second terminal of the coil 2 through the output terminal 20. With this configuration, a π-type filter circuit wherein one coil is disposed between two capacitors (capacitor-coil-capacitor) is obtained.

The conductive shielding plate 4 which is the most characteristic part of the present invention is provided for shielding electric field coupling between the pair of capacitors 3a and 3b. The conductive shielding plate 4 is grounded to the ground plate 1 and is electrically connected to the ground plate 1. The conductive shielding plate 4 extends through a predetermined through-hole formed in the casing 30 so as to be disposed inside the casing 30. As with the abovementioned ground terminals 15 and 16, the conductive shielding plate 4 may be formed by bending at right angles a part of the ground plate 1 to raise it upright or may be electrically connected to the ground plate 1 by soldering, etc. It is only necessary for the conductive shielding plate 4 to be interposed between the pair of capacitors 3a and 3b. In the illustrative example, the conductive shielding plate 4 is disposed between the capacitor 3a and the coil 2. However, the present invention is not limited to this, but the conductive shielding plate 4 may be disposed between the capacitor 3b and the coil 2.

In particular, as is clear from FIG. 1 (b), the interposition of the conductive shielding plate 4 between the capacitor 3a and the coil 2 achieves shielding of electric field coupling between the pair of capacitors 3a and 3b. This suppresses the electric field coupling between the pair of capacitors 3a and 3b even in FM radio band, enabling high noise attenuation performance to be exerted.

Further, since the conductive shielding plate 4 is provided for shielding the electric field coupling between the pair of capacitors 3a and 3b, an increase in the height of the conductive shielding plate 4 allows an increase in the shield factor of the electric field coupling. The conductive shielding plate 4 extending from the ground plate 1 may be further bent so as to cover the upper portion of the capacitor.

Further, the pair of capacitors may be disposed such that lower height surfaces thereof are opposed to each other so as to reduce the opposing area thereof. The details of this will be described later. This makes it possible to reduce the electric field coupling between the pair of capacitors. Further, the pair of capacitors need not be disposed completely opposite to each other but may be disposed slightly shifted in position from each other in the horizontal direction as in the illustrative example.

In the case of a π-type filter assuming a configuration of an equivalent series inductor of capacitor part—an equivalent parallel circuit of coil part inductor and coupling capacitance—an equivalent series inductor of capacitor part in a high-frequency band, connection of the coil parts by a ¼ wavelength line makes it possible to increase the attenuation amount obtained by the equivalent series inductor of the capacitor part to more than twice. That is, the attenuation characteristics of the filter circuit having such a configuration are dominated by the attenuation amount obtained by the equivalent series inductor of the capacitor part. Note that resonance of the equivalent parallel circuit of the coil part allows addition of the attenuation amount obtained by the equivalent parallel circuit to the attenuation amount obtained by the ¼ wavelength line, thereby obtaining a larger attenuation amount.

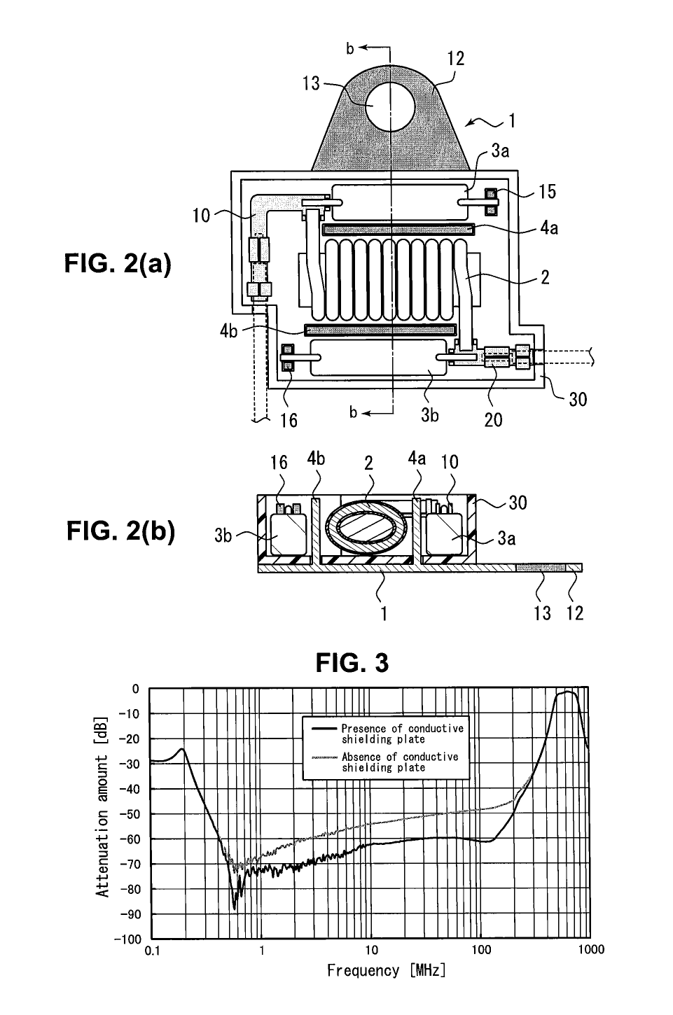

A vehicle-mounted noise filter according to a second embodiment of the present invention will be described. FIG. 2 is a schematic view for explaining an arrangement example of components of a vehicle-mounted noise filter according to the second embodiment of the present invention. FIG. 2 (a) is a top view, and FIG. 2 (b) is a cross-sectional view taken along the b-b line of FIG. 2 (a). In FIG. 2, the parts having the same reference numerals as in FIG. 1 are substantially identical with those of the same reference numbers shown in FIG. 1.

As illustrated, the vehicle-mounted noise filter according to the second embodiment of the present invention differs from that of the first embodiment in that the conductive shielding plate is disposed between one coil and each of the pair of capacitors. More specifically, the vehicle-mounted noise filter according to the second embodiment has two conductive shielding plates 4a and 4b, one of which is disposed between the capacitor 3a and the coil 2, and the other of which is disposed between the capacitor 3b and the coil 2. As in the first embodiment, the conductive shielding plates 4a and 4b are each grounded to the ground plate 1 through a predetermined through-hole formed in the casing.

As described above, the vehicle-mounted noise filter according to the second embodiment of the present invention is configured to shield electric field coupling between the capacitors by using the two conductive shielding plates. Thus, in the second embodiment, the electric field coupling between the capacitors can be shielded more reliably than in the case of the first embodiment.

Effects of the vehicle-mounted noise filter of the present invention will be described using FIG. 3. FIG. 3 is a graph of input/output characteristics with respect to the frequency of the vehicle-mounted noise filter of the present invention. The input/output characteristics of FIG. 3 are characteristics of the vehicle-mounted noise filter illustrated in FIG. 2, and characteristics in the absence of the conductive shielding plate is represented by a gray line as a comparative example.

As illustrated, it can be seen that the attenuation amount is smaller in the vehicle-mounted noise filter of the present invention having the conductive shielding plate than in the vehicle-mounted noise filter having no conductive shielding plate. That is, it is understood that the electric field coupling between the pair of capacitors can be shielded by the conductive shielding plate.

The illustrated input/output characteristics are merely an example and are influenced also by the characteristics of the filter circuit itself. Thus, it is possible to further enhance the noise attenuation characteristics by optimization of a filter constant.

Further, when two conductive shielding plates are used to sandwich the coil as in the case of the vehicle-mounted noise filter according to the second embodiment of the present invention, heat of the coil generated by applying current can be transferred to the conductive shielding plates so as to be released to the ground plate. This advantageously reduces heat transfer to the capacitor side. That is, the conductive shielding plates can not only shield the electric field coupling but also bring about heat radiation effect. As a result, it is possible to stabilize the temperature characteristics of the capacitor.

Other configuration and effects are the same as those of the first embodiment, and the detailed description are omitted.

Assuming that the phase delay is set to 90° by the coil, a potential difference can be generated between the ground terminals 15 and 16, so that it is preferable that the ground terminals 15 and 16 are securely grounded. If the grounding is insufficient, a potential difference occurs also between the conductive shielding plates 4a and 4b, reducing the electric field shielding effect.

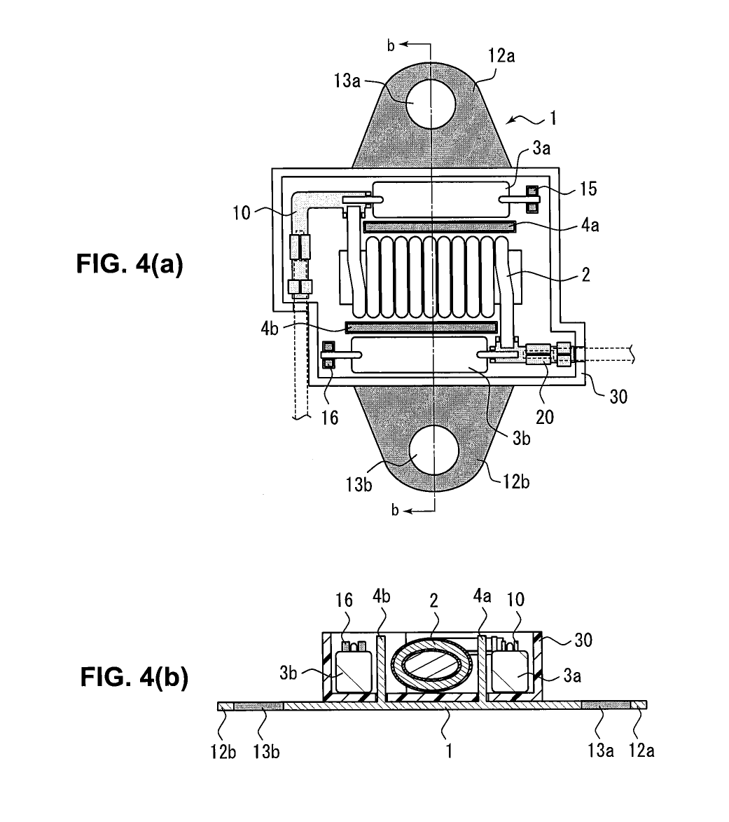

In the following, a structure for achieving more secure grounding will be described. FIG. 4 is a schematic view for explaining an arrangement example of components of a vehicle-mounted noise filter according to a third embodiment of the present invention. FIG. 4 (a) is a top view, and FIG. 4 (b) is a cross-sectional view taken along the b-b line of FIG. 4 (a). In FIG. 4, the parts having the same reference numerals as in FIGS. 1 and 2 are substantially identical with those of the same reference numbers shown in FIGS. 1 and 2.

As illustrated, the vehicle-mounted noise filter according to the third embodiment of the present invention differs from those of the first and second embodiments in that the flared portions of the ground plate are symmetrically disposed with respect to the coil. More specifically, in the first and second embodiments, the ground plate 1 is provided so as to cover substantially the entire rear surface of the casing 30 and has the flared portion 12 for fixation to the vehicle body only on one side (upper side in FIGS. 1 and 2). On the other hand, in the third embodiment, the ground plate 1 covers substantially the entire rear surface of the casing 30 and has flared portions 12a and 12b symmetrically disposed with respect to the coil 2. Connection holes 13a and 13b for screwing to the vehicle body are formed in the flared portions 12a and 12b, and the vehicle-mounted noise filter is securely screwed to the vehicle body through the connection holes 13a and 13b. With this configuration, the ground terminals 15 and 16 are securely grounded to the vehicle body, preventing the potential difference from being generated.

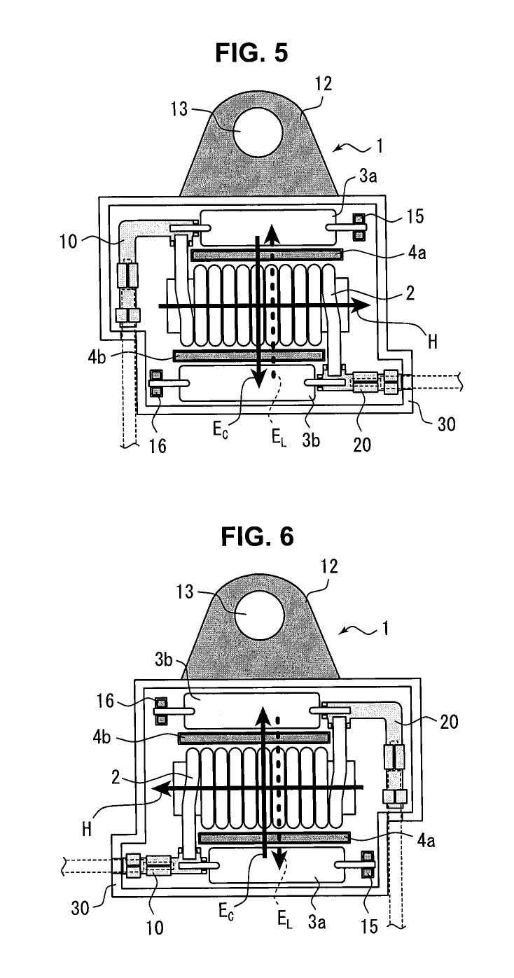

A relationship between the winding direction of the coil conductive wire and the electric field direction of the electric field coupling generated between the pair of capacitors in the first to third embodiments will be described. FIG. 5 is a top view for explaining the electric field direction in the vehicle-mounted noise filter according to the present invention. In FIG. 5, the parts having the same reference numerals as in FIG. 2 are substantially identical with those of the same reference numbers shown in FIG. 5. The vehicle-mounted noise filter of FIG. 5 is obtained by adding the electric field direction to the vehicle-mounted noise filter of the second embodiment illustrated in FIG. 2.

When the capacitor 3a connected to the input terminal 10 has a positive charge, a negative charge is generated in the capacitor 3b connected to the output terminal 20. At this time, as illustrated, the pair of capacitors 3a and 3b whose ends are short-circuited are electric-field coupled by an electric field E_{c} going from the capacitor 3a to the capacitor 3b.

Assuming that a leakage electric field caused by a magnetic field generated in the coil 2 disposed between the pair of capacitors 3a and 3b goes from the capacitor 3b to the capacitor 3a, the electric field E_{c} can be canceled. That is, when the conductive wire of the coil 2 is wound so as to generate a magnetic filed H causing a leakage electric field E_{L} in the direction canceling the electric field E_{c} by which the pair of capacitors 3a and 3b is electric-field coupled, the electric field coupling between the pair of capacitors 3a and 3b can be suppressed.

More specifically, the pair of capacitors are electric-field coupled in the direction from the capacitor 3a connected to the input terminal 10 to the capacitor 3b connected to the output terminal 20, so that when the capacitor 3a is disposed on the axially left side of the coil 2 as viewed from the input terminal 10, the coil 2 should be wound left-handed. This causes a magnetic field in the direction from the input terminal 10 to the output terminal 20, which in turn causes the leakage electric field E_{L} in the direction from the capacitor 3b to the capacitor 3a.

FIG. 6 is a top view for explaining an example in which the coil winding direction and the arrangement position of the capacitors in the vehicle-mounted noise filter according to the present invention illustrated in FIG. 5 are reversed. In FIG. 6, the parts having the same reference numerals as in FIG. 5 are substantially identical with those of the same reference numbers shown in FIG. 5. When the capacitor 3a is disposed on the axially right side of the coil 2 as viewed from the input terminal 10 as illustrated in FIG. 6, the coil 2 should be wound right-handed. This causes a magnetic field in the direction from the output terminal 20 to the input terminal 10, which in turn causes the leakage electric field E_{L} in the direction from the capacitor 3b to the capacitor 3a.

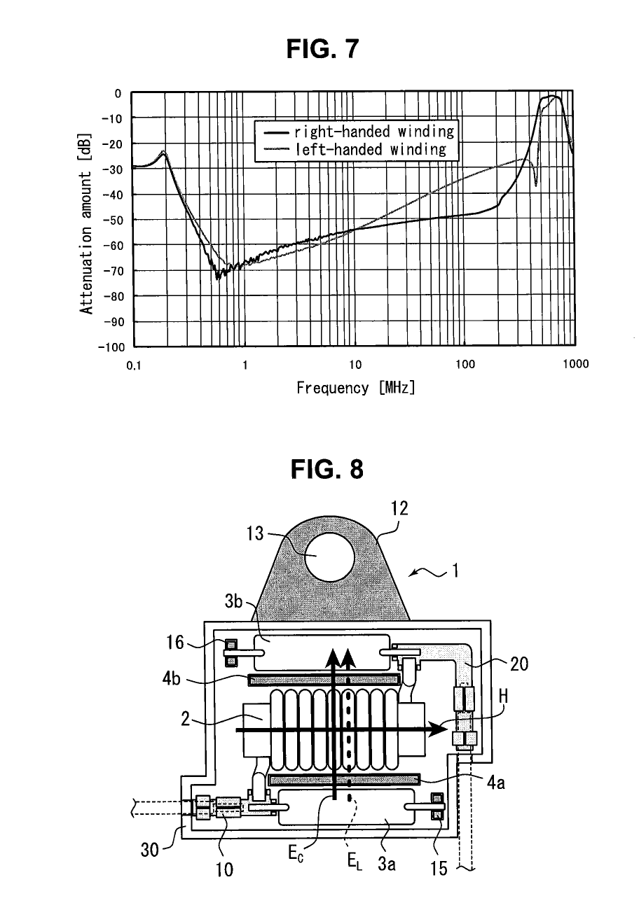

By taking the coil winding direction and arrangement position of the capacitors into consideration as described above, the electric field coupling between the pair of capacitors can be suppressed. Here, using FIG. 7, influence on the input/output characteristics due to a difference in the coil winding direction will be described. FIG. 7 represents the input/output characteristics of a right-handed-wound coil and a left-handed-wound coil, respectively. More specifically, the characteristic curve of the right-handed-wound coil represents the characteristics obtained in the case where the right-handed-wound coil and capacitors are arranged as illustrated in FIG. 6. The characteristic curve of the left-handed-wound coil represents the characteristics obtained in the configuration illustrated in FIG. 8 where the left-handed coil and the capacitors are arranged in the same manner as in FIG. 6, that is, where the electric field coupling between the capacitors is not suppressed. For simplification of the phenomenon, measurement was performed using a vehicle-mounted noise filter not having the conductive shielding plate.

As illustrated, it can be seen that when the coil is wound right-handed, that is, when the coil is wound in such a direction so as to generate a leakage electric field in the direction canceling the electric field by which the capacity pair is electric-field coupled, the attenuation amount is reduced more especially in a high-frequency band.

The same result can be obtained even in the case where the conductive shielding plate of the present invention is provided, and the addition of effect resulting from the coil winding direction to the effect resulting from the use of the conductive shielding plate allows a further reduction in the attenuation amount especially in a high-frequency band.

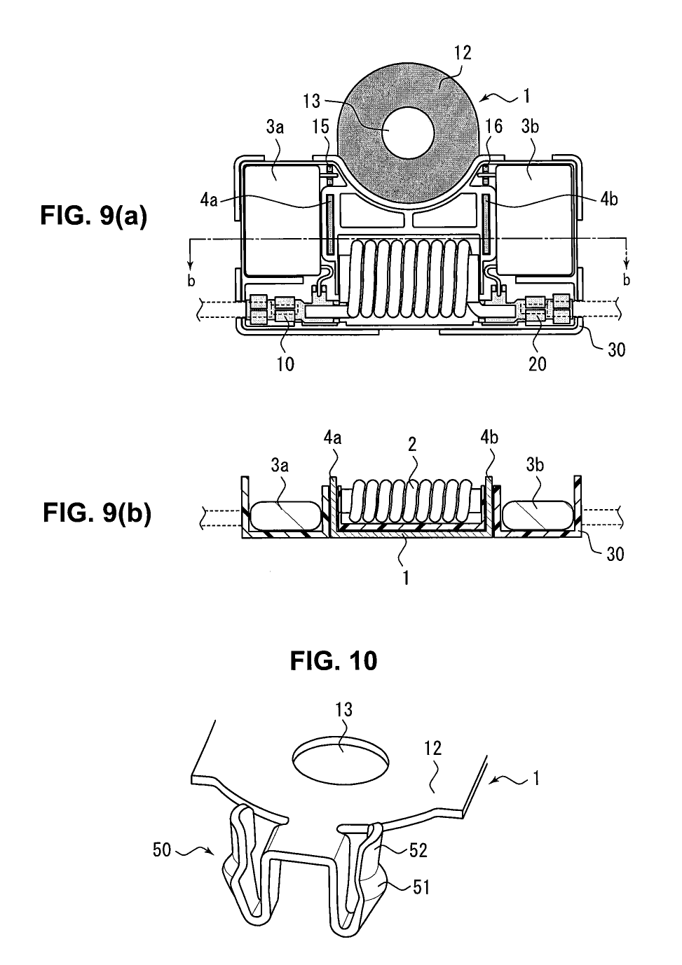

A vehicle-mounted noise filter according to a fourth embodiment of the present invention will be described. FIG. 9 is a schematic view for explaining an arrangement example of components of a vehicle-mounted noise filter according to a fourth embodiment of the present invention. FIG. 9 (a) is a top view, and FIG. 9 (b) is a cross-sectional view taken along the b-b line of FIG. 9 (a). In FIG. 9, the parts having the same reference numerals as in FIG. 1 are substantially identical with those of the same reference numbers shown in FIG. 1.

As illustrated, the vehicle-mounted noise filter according to the fourth embodiment has a configuration in which the pair of capacitors 3a and 3b are disposed such that surfaces of the capacitors 3a and 3b smaller in area are opposed to each other so as to reduce the opposing area. More specifically, the pair of capacitors 3a and 3b are disposed such that lower height surfaces thereof are opposed to each other. For example, a ceramic capacitor, etc., is composed of wide front surfaces and narrow side surfaces, and by disposing the narrow side surfaces opposite to each other, the opposing area can be reduced. This can further suppress the electric field coupling between the pair of capacitors. Further, the opposing disposition of the smaller surfaces in area allows achievement of a reduction in the thickness of the vehicle-mounted noise filter.

Further, in the illustrative example, the pair of capacitors 3a and 3b are disposed opposite to each other so as to sandwich the coil from both side parallel to the direction perpendicular to the axis of the coil 2. With this arrangement, the sides of the coil 2 parallel to the axial direction of the coil 2 are opened. The heat generated in the coil 2 is generally radiated in the side direction of the coil. Thus, opening of the sides of the coil 2 enhances heat radiation effect to reduce heat transfer to the capacitors 3a and 3b.

The ground plate 1 has the flared portion 12 for fixation to the vehicle body, and at least a part of the flared portion 12 is disposed between the opposing pair of capacitors 3a and 3b. More specifically, at least a part of the flared portion 12 is disposed so as to protrude to the coil 2 side between the pair of capacitors 3a and 3b to such a degree that the connection hole 13 of the flared portion 12 does not interfere with the coil 2. This allows a size reduction of the vehicle-mounted noise filter.

Further, in the fourth embodiment, the flared portion 12 is formed so as to make equal the distances therefrom to connection points at which the capacitors 3a and 3b are connected respectively to the ground plate 1. That is, the distance from the connection hole 13 of the flared portion 12 to the ground terminal 15 and the distance from the connection hole 13 to the ground terminal 16 are made equal to each other. More specifically, the relationship between the connection hole 13 of the flared portion 12 and each of the ground terminals 15 and 16 is provided so as to be line-symmetric with respect to the center line perpendicular to the axis of the coil 2. This makes it hard to generate a potential difference between the ground terminals 15 and 16, ensuring stable grounding.

Further, as in the abovementioned embodiments, the two conductive shielding plates 4a and 4b are disposed between the capacitor 3a and the coil 2 and between the capacitor 3b and the coil 2, respectively. Further, the equality of the distance between the conductive shielding plate 4a and the connection hole 13 of the flared portion 12 and the distance between the conductive shielding plate 4b and the connection hole 13 allows the conductive shielding plates 4a and 4b to shield the electric field reliably. Further, transfer of the heat generated in the coil 2 to the conductive shielding plates 4a and 4b enables the temperature characteristics of the capacitor to be stabilized.

Further, in the fourth embodiment, as illustrated, the conductive wire is wound around the coil 2 such that the end portions of the conductive wire at both ends of the coil 2 extend in the same direction and are at the same height position (in addition, the direction is opposite 180 degrees). The input terminal 10 and the output terminal 20 are disposed parallel to the axis of the coil 2. As a result, the symmetric stricture can be obtained, including the input and output terminals.

When there is a difference between the grounding paths of the input and output capacitors, a potential difference occurs in the input-side and output-side capacitors in a high-frequency band, and an electric field generated by the capacitor is added to or subtracted from an electric field generated from the coil depending on the coil winding design, which may result in occurrence of an electric field variation. This may eventually adversely affect the electric field coupling between the input and output. However, when the ground terminals 15 and 16, the conductive shielding plates 4a and 4b, and the conductive wire of the coil are disposed symmetric with respect to the center line perpendicular to the axis of the coil 2 as in the fourth embodiment, electrically stable state can be established between the input and output. Thus, it is possible to reduce the attenuation amount stably especially in a high-frequency band without being influenced by the coil winding direction, etc.

As described above, the vehicle-mounted noise filter according to the fourth embodiment of the present invention can significantly reduce the coupling degree between the capacitors, achieve an electrically stable state, and enable a reduction in size and thickness.

The flared potion of the ground plate will be described using FIG. 10. FIG. 10 is a perspective view for explaining an example of the flared portion of the ground plate of the vehicle-mounted noise filter according to the present invention. As illustrated, the flared portion may have a temporary latching claw 50 to be latched in a temporary latching hole (not illustrated) formed in the vehicle body. The temporary latching claw 50 has a latching portion 51 to be inserted into the temporary latching hole and a tab portion 52 used to remove, as necessary, the temporary latching claw 50 from the temporary latching hole after the insertion. To fix the vehicle-mounted noise filter to the vehicle body, first the temporary latching claw 50 is inserted into the temporary latching hole formed in the vehicle body, whereby the noise filter and vehicle body are temporarily fixed. After that, a screw or the like is screwed to the connection hole 13, thereby facilitating the fixation to the vehicle body. In the case where the vehicle-mounted noise filter has gone wrong, pinching the tab portion 52 allows the vehicle-mounted noise filter to be removed easily for replacement.

The vehicle-mounted noise filter of the present invention is not limited to the above illustrative examples but various modifications may be made without departing from the scope of the present invention. For example, as disclosed in Japanese Patent Application No. 2008-138750 filed by the present inventor, a shielding plate for shielding the electric filed coupling between input and output terminals may also be employed in the vehicle-mounted noise filter.

### EXPLANATION OF REFERENCE SYMBOLS

1: Ground plate
2: Coil
3a, 3b: Capacitor
4, 4a, 4b: Conductive shielding plate
10: Input terminal
12, 12a, 12b: Flared portion
13, 13a, 13b: Connection hole
15, 16: Ground terminal
20: Output terminal
30: Casing
50: Temporary latching claw
51: Latching portion
52: Tab portion

1. A vehicle-mounted noise filter comprising:
a ground plate for grounding to a vehicle body;
a coil around which a conducting wire is wound;
a pair of capacitors disposed so as to sandwich the coil and electrically connected to the coil and the ground plate so as to provide a π-type filter circuit; and
a conductive shielding plate disposed between the pair of capacitors so as to shield electric field coupling between the pair of capacitors and grounded to the ground plate.

2. The vehicle-mounted noise filter according to claim 1, in which the conductive shielding plate is disposed between one coil and each of the pair of capacitors.

3. The vehicle-mounted noise filter according to claim 1, in which the conducting wire of the coil is wound in such a direction so as to generate a leakage electric field in the direction canceling the electric field of the electric filed coupling generated between the pair of capacitors.

4. The vehicle-mounted noise filter according to claim 3, in which when the capacitor connected to an input terminal side is disposed on the axially right side of the coil as viewed from the input terminal of the vehicle mounted noise filter, the coil is wound right-handed, while when the capacitor connected to the input terminal side is disposed on the axially left side of the coil, the coil is wound left-handed.

5. The vehicle-mounted noise filter according to claim 1, in which the pair of capacitors are disposed such that surfaces thereof smaller in area are opposed to each other so as to reduce the opposing area.

6. The vehicle-mounted noise filter according to claim 5, in which the pair of capacitors are disposed opposite to each other so as to sandwich the coil from both side parallel to the direction perpendicular to the axis of the coil.

7. The vehicle-mounted noise filter according to claim 6, in which the ground plate has a flared portion for fixing to the vehicle body, and at least part of the flared portion is disposed between the opposing pair of capacitors.

8. The vehicle-mounted noise filter according to claim 5, in which the ground plate has a flared portion for fixing to the vehicle body, and the flared portion is formed so as to make equal the distances therefrom to connection points at which the pair of capacitors are connected respectively to the ground plate.

9. The vehicle-mounted noise filter according to claim 5, in which the conducting wire is wound around the coil such that the end portions of the conducting wire at both ends of the coil extend in the same direction and are at the same height position.

10. The vehicle-mounted noise filter according to claim 1, in which the ground plate has a flared portion for fixing to the vehicle body, and the flared portion has a temporary latching claw to be latched in a temporary latching hole formed in the vehicle body.
